(19) United States
(12) Patent Application Publication
(10) Pub. No.: US 2013/0278114 A1
(43) Pub. Date: Oct. 24, 2013

(54) PIEZOELECTRIC DEVICE AND METHOD FOR FABRICATING THE SAME

(71) Applicant: NIHON DEMPA KOGYO CO., LTD., Tokyo (JP)

(72) Inventors: TAICHI HAYASAKA, SAITAMA (JP); SHUICHI MIZUSAWA, SAITAMA (JP)

(73) Assignee: NIHON DEMPA KOGYO CO., LTD., Tokyo (JP)

(21) Appl. No.: 13/868,112

(22) Filed: Apr. 23, 2013

(30) Foreign Application Priority Data
Apr. 24, 2012 (JP) 2012-098406

(51) Int. Cl. H01L 41/047; H01L 41/29; H01L 41/053

(52) U.S. Cl. CPC H01L 41/0475; H01L 41/053; H01L 41/29
USPC 310/344; 156/150; 156/280

(57) ABSTRACT

A surface mount piezoelectric device includes a piezoelectric vibrating piece, a base plate, and a lid plate. The piezoelectric vibrating piece includes a vibrating portion. The base plate has one principal surface that includes a pair of mounting terminals and another principal surface where the piezoelectric vibrating piece is placed. The mounting terminals include a metal film formed by sputtering or vacuum evaporation and electroless plating film formed on a surface of the metal film. The lid plate has one principal surface that includes a metal film and an electroless plating film formed on a surface of the metal film by electroless plating and another principal surface seals the vibrating portion. The electroless plating film formed on the one principal surface of the base plate and the electroless plating film formed on the one principal surface of the lid plate have mutually a same shape and a same area.

### CROSS REFERENCE TO RELATED APPLICATIONS

This application claims the priority benefit of Japan application serial no. 2012-098406, filed on Apr. 24, 2012. The entirety of the above-mentioned patent application is hereby incorporated by reference herein and made a part of this specification.

### TECHNICAL FIELD

This disclosure relates to a piezoelectric device that includes an electrode formed by electroless plating and a method for fabricating the piezoelectric device.

### DESCRIPTION OF THE RELATED ART

A surface mount piezoelectric device that includes a piezoelectric vibrating piece, which vibrates at a predetermined vibration frequency, is known. A mounting terminal is formed on a surface of the piezoelectric device as an electrode. The piezoelectric device is mounted to a printed circuit board or similar member via this mounting terminal. Since the mounting terminal is formed on the surface of the piezoelectric device, the mounting terminal may be detached by heating of a solder or similar cause or may be damaged. Therefore, with the piezoelectric device, a thick film is formed on the mounting terminal by plating or similar method to ensure conduction. Additionally, the thick film formed by plating is also formed as a barrier layer that prevents the solder from absorbing a metal of the mounting terminal.

For example, Japanese Unexamined Patent Application Publication No. 2000-252375 discloses a mounting terminal formed with a conductive paste and a plating layer formed on a surface of the conductive paste.

However, since the plating layer is formed thick, the plating layer may generate stress to the piezoelectric device. The stress generated in the piezoelectric device warps the piezoelectric device, which causes a problem of detachment of the plating layer or the mounting terminal including the plating layer. Especially, this detachment occurs in a fabrication of the piezoelectric device, which employs a method where a plurality of piezoelectric devices is formed on a wafer, and then the wafer is diced to form individual piezoelectric devices. This is because that stress generated in the piezoelectric device changes while cutting the wafer, thus increasing distortion of the piezoelectric device.

A need thus exists for a piezoelectric device and a method for fabricating the piezoelectric device which are not susceptible to the drawback mentioned above.

### SUMMARY

A piezoelectric device according to a first aspect is a surface mount piezoelectric device that includes a piezoelectric vibrating piece, a base plate, and a lid plate. The piezoelectric vibrating piece includes a vibrating portion that vibrates at a predetermined vibration frequency. The base plate has one principal surface and another principal surface. The one principal surface includes a pair of mounting terminals. The piezoelectric vibrating piece is placed on the other principal surface. The pair of mounting terminals includes a metal film formed by sputtering or vacuum evaporation and an electroless plating film formed on a surface of the metal film. The piezoelectric device is to be mounted with the pair of mounting terminals. The lid plate has one principal surface and another principal surface. The one principal surface includes a metal film and an electroless plating film formed on a surface of the metal film by electroless plating. The other principal surface seals the vibrating portion. The electroless plating film formed on the one principal surface of the base plate and the electroless plating film formed on the one principal surface of the lid plate have mutually a same shape and a same area.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a piezoelectric device 100;

FIG. 2(a) is a cross-sectional view taken along the line IIA-IIA of FIG. 1;

FIG. 2(b) is an enlarged view of the portion enclosed by a dotted line 161 of FIG. 2(a);

FIG. 2(c) is an enlarged view of a dotted line 162 of FIG. 2(a);

FIG. 3(a) is a plan view of the surface at the −Y′-axis side of a base plate 120;

FIG. 3(b) is a plan view of the surface at the +Y′-axis side of a lid plate 110;

FIG. 4 is a flowchart illustrating a method for fabricating the piezoelectric device 100;

FIG. 5(a) is a plan view of the surface at the +Y′-axis side of a base wafer W120;

FIG. 5(b) is a plan view of the surface at the −Y′-axis side of the base wafer W120;

FIG. 6 is a plan view of the surface at the +Y′-axis side of a lid wafer W110;

FIG. 7(a) is a partial cross-sectional view of the base wafer W120 where a piezoelectric vibrating piece 130 is placed;

FIG. 7(b) is a partial cross-sectional view of the lid wafer W110, the piezoelectric vibrating piece 130, and the base wafer W120;

FIG. 7(c) is a partial cross-sectional view of the lid wafer W110 where an electroless plating film 153 is formed, the piezoelectric vibrating piece 130, and the base wafer W120 where the electroless plating film 153 is formed;

FIG. 8 is a graph illustrating a relationship between a thickness TN of a nickel (Ni) layer of the electroless plating film 153 and a detachment rate of the electroless plating film 153;

FIG. 9 is an exploded perspective view of a piezoelectric device 200;.

FIG. 10(a) is a cross-sectional view taken along the line XA-XA of FIG. 9;

FIG. 10(b) is an enlarged view of the portion enclosed by a dotted line 163 of FIG. 10(a);

FIG. 10(c) is an enlarged view of the portion enclosed by a dotted line 164 of FIG. 10(a);

FIG. 11 is a flowchart illustrating a method for fabricating the piezoelectric device 200

FIG. 12(a) is a partial cross-sectional view of a piezoelectric wafer, a lid wafer, and a base wafer;

FIG. 12(b) is a partial cross-sectional view of the piezoelectric wafer, and the lid wafer and the base wafer where second metal films are formed; and

FIG. 12(c) is a partial cross-sectional view of the piezoelectric wafer, and the lid wafer and the base wafer where electroless plating films are formed.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

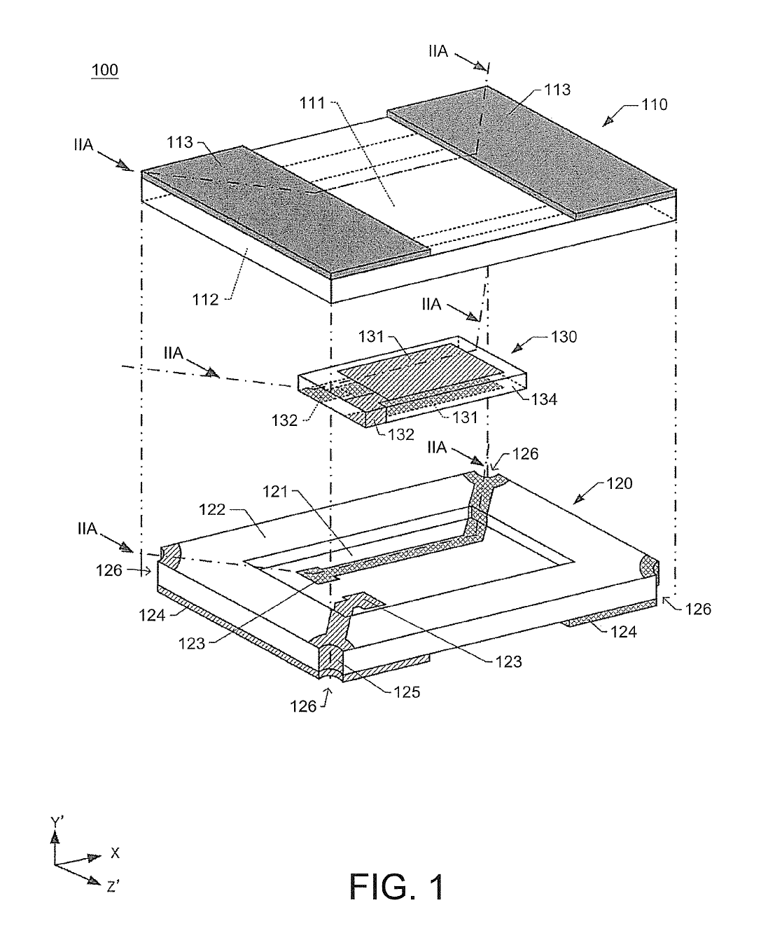

FIG. 1 is an exploded perspective view of the piezoelectric device 100. The piezoelectric device 100 includes a lid plate 110, a base plate 120, and a piezoelectric vibrating piece 130. An AT-cut quartz-crystal vibrating piece, for example, is employed for the piezoelectric vibrating piece 130. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

The piezoelectric vibrating piece 130 includes a vibrating portion 134, an excitation electrode 131, and an extraction electrode 132. The vibrating portion 134 vibrates at a predetermined vibration frequency and has a rectangular shape.

The excitation electrodes 131 are formed on surfaces at the +Y′-axis side and the −Y′-axis side of the vibrating portion 134. The extraction electrode 132 is extracted from each excitation electrode 131 to the −X-axis side. The extraction electrode 132 is extracted from the excitation electrode 131, which is formed on the surface at the +Y′-axis side of the vibrating portion 134. The extraction electrode 132 is extracted from the excitation electrode 131 to the −X-axis side, and is further extracted to the surface at the −Y′-axis side of the vibrating portion 134 via the side surface at the +Z′-axis side of the vibrating portion 134. The extraction electrode 132 is extracted from the excitation electrode 131, which is formed on the surface at the −Y′-axis side of the vibrating portion 134. The extraction electrode 132 is extracted from the excitation electrode 131 to the −X-axis side, and is formed up to the corner at the −X-axis side and the −Z′-axis side of the vibrating portion 134.

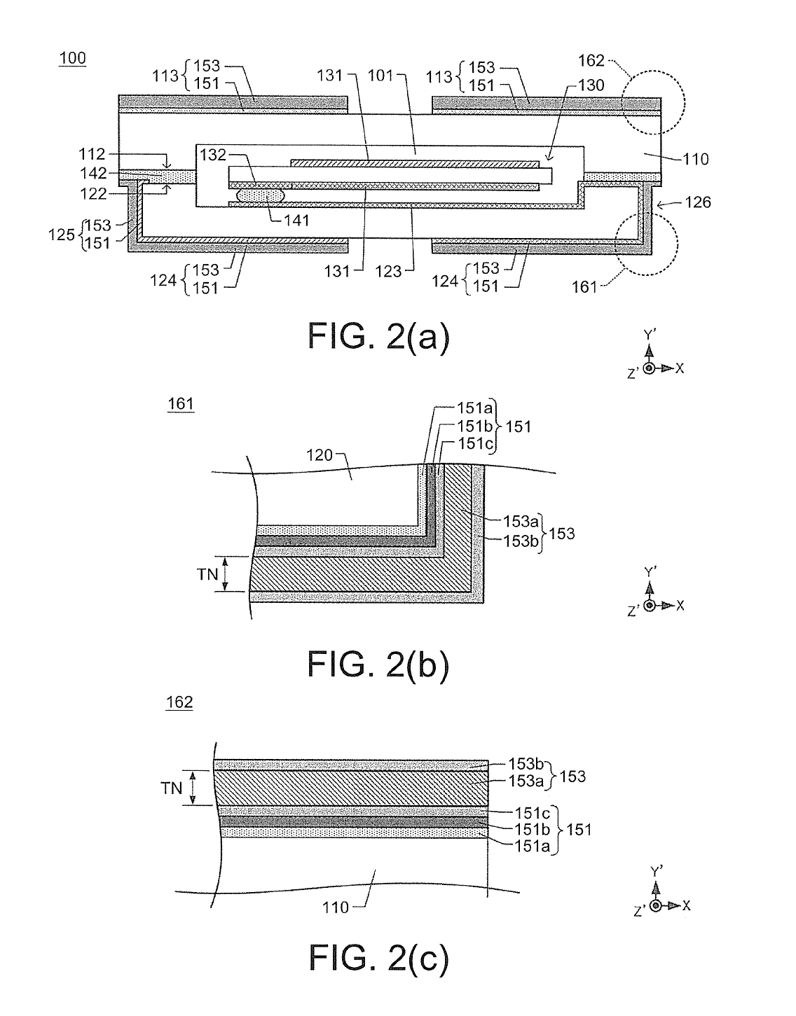

The base plate 120 employs a material such as a crystal and a glass as a base material. An electrode is formed on a surface of this base material. A bonding surface 122 is formed at the peripheral area of the surface at the +Y′-axis side of the base plate 120. The bonding surface 122 is to be bonded to the lid plate 110 via a sealing material 142 (see FIG. 2(a)). The base plate 120 includes a depressed portion 121 at the center of the surface at the +Y′-axis side. The depressed portion 121 is depressed from the bonding surface 122 in the −Y′-axis direction. A pair of connecting electrodes 123 is formed in the depressed portion 121. Each connecting electrode 123 electrically connects to an extraction electrode 132 of the piezoelectric vibrating piece 130 via a conductive adhesive 141 (see FIG. 2(a)). The base plate 120 includes a mounting terminal 124 on the surface at the −Y′-axis side. The mounting terminal 124 is employed for mounting the piezoelectric device 100 to a printed circuit board or similar member. Castellations 126 are formed at four corners on side surfaces of the base plate 120. The castellation 126 is depressed toward inside of the base plate 120. A side surface electrode 125 is formed at the side surface of the castellation 126. The mounting terminal 124 electrically connects to the connecting electrode 123 via the side surface electrode 125.

The lid plate 110 includes a depressed portion 111 on the surface at the −Y′-axis side. The depressed portion 111 is depressed in the +Y′-axis direction. A bonding surface 112 is formed for surrounding the depressed portion 111. The bonding surface 112 is bonded to the bonding surface 122 of the base plate 120 via the sealing material 142 (see FIG. 2(a)). Moreover, a lid film 113 is formed on the surface at the +Y′-axis side of the lid plate 110.

FIG. 2(a) is a cross-sectional view taken along the line IIA-IIA of FIG. 1. A sealed cavity 101 is formed in the piezoelectric device 100 by bonding the bonding surface 122 of the base plate 120 and the bonding surface 112 of the lid plate 110 together via the sealing material 142. The cavity 101 houses the piezoelectric vibrating piece 130. The extraction electrode 132 electrically bonds to the connecting electrode 123 of the base plate 120 via the conductive adhesive 141. This electrically connects the excitation electrode 131 to the mounting terminal 124.

The mounting terminal 124 is formed of a first metal film 151 formed on the surface at the −Y′-axis side of the base material of the base plate 120 and an electroless plating film 153 formed on the surface of the first metal film 151. Furthermore, the lid film 113 formed on the surface at the +Y′-axis side of the lid plate 110 includes the first metal film 151 formed on the surface at +Y′-axis side of the base material of the lid plate 110 and the electroless plating film 153 formed on the surface of the first metal film 151.

FIG. 2(b) is an enlarged view of the portion enclosed by a dotted line 161 of FIG. 2(a). FIG. 2(b) illustrates an enlarged cross-sectional view of the mounting terminal 124. The first metal film 151 is formed of three layers: a first layer 151a, a second layer 151b, and a third layer 151c. The first layer 151a is a layer made of a chrome (Cr) and is formed on a surface of the base material of the base plate 120. The chrome (Cr) is employed as a material of the first layer 151a for good adhesion to a material such as a crystal and a glass, which is the base material of the base plate 120. The third layer 151c, which is formed on a surface of the first metal film 151, is made of a gold (Au). A chrome (Cr) adheres well to a material such as a crystal and a glass, but does not stick to solder or similar material. Accordingly, the surface of the first metal film 151 is covered with a gold (Au), which sticks to a solder or similar material well. Further, in the first metal film 151, the second layer 151b is formed between the first layer 151a and the third layer 151c. When heat or the like is applied to the chrome (Cr), which constitutes the first layer 151a, during a fabrication process, the chrome (Cr) spreads to another layer. This reduces adhesion between the chrome (Cr) and the base plate 120. Further, when the chrome (Cr) spreads to a surface of the first metal film 151, the chrome (Cr) oxidizes, making formation of the electroless plating film 153 or similar member difficult. To prevent this spread of the chrome (Cr), the second layer 151b is disposed. This prevents the chrome (Cr) from spreading to the gold (Au) layer.

The second layer 151b is formed of, for example, a nickel tungsten (Ni—W). The second layer 151b may be made of platinum (Pt). For example, when platinum (Pt) is employed, the first layer 151a is formed to have a thickness of 300 angstroms to 500 angstroms, the second layer 151b is formed to have a thickness of 1000 angstroms to 2000 angstroms, and the third layer 151c is formed to have a thickness of 1000 angstroms to 2000 angstroms. An electrode that includes the electroless plating film 153 is, when compared with an electrode that does not include the electroless plating film 153, likely to cause detachment due to distortion of the base plate 120 by stress generated by the electroless plating film 153. In the first metal film 151, formation of the second layer 151b prevents spread of the chrome (Cr), thus holding strong adhesion between the first metal film 151 and the base material of the base plate 120. This prevents detachment of the first metal film 151.

The electroless plating film 153 is formed of a first layer 153a and a second layer 153b. The first layer 153a is formed on a surface of the first metal film 151. The second layer 153b is formed on a surface of the first layer 153a. The first layer 153a is a nickel (Ni) layer and has the thickness TN of 1 μm to 3 μm. To ensure connection of the mounting terminal 124 and a solder or similar material, the second layer 153b made of a gold (Au) is formed on a surface of the first layer 153a.

FIG. 2(c) is an enlarged view of a dotted line 162 of FIG. 2(a). FIG. 2(c) illustrates an enlarged cross-sectional view of the lid film 113. The lid film 113 is formed of the first metal film 151 formed on the surface at the +Y′-axis side of the base material of the lid plate 110 and the electroless plating film 153 formed on the surface of the first metal film 151. The first metal film 151 and the electroless plating film 153 forming the lid film 113 are formed with the same constitution as the first metal film 151 and the electroless plating film 153 of the mounting terminal 124 as illustrated in FIG. 2(b). Furthermore, the thickness TN of the first layer 153a of the base plate 120 is the same as the thickness TN of the first layer 153a of the lid plate 110.

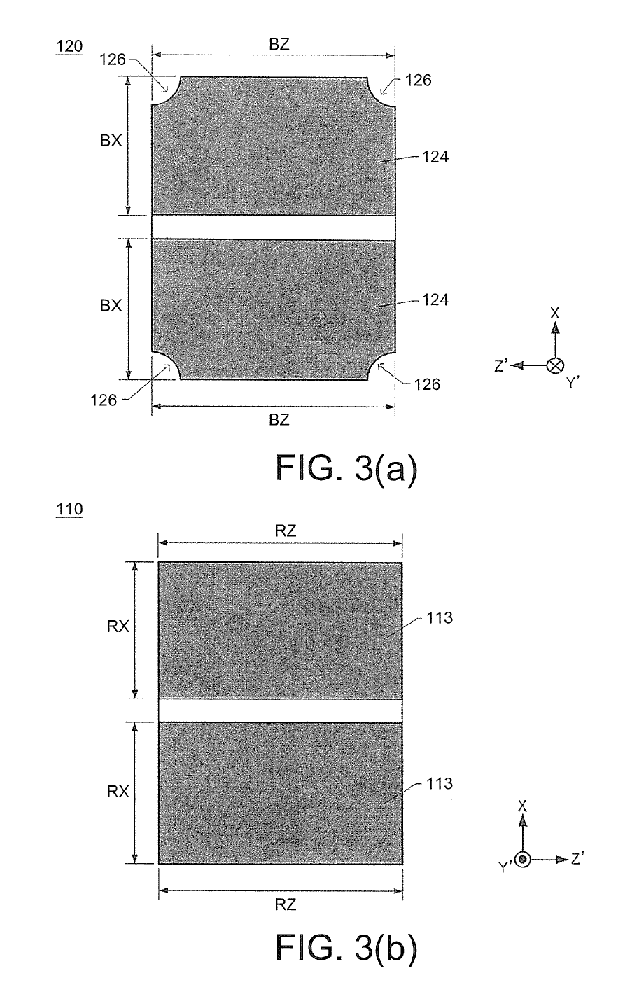

FIG. 3(a) is a plan view of the surface at the −Y′-axis side of the base plate 120. On the surface at the −Y′-axis side of the base plate 120, the pair of the mounting terminals 124 is formed at the +X-axis side and the −X-axis side of the base plate 120. Each mounting terminal 124 is formed to have a length BX in the X-axis direction and a length BZ in the Z′-axis direction.

FIG. 3(b) is a plan view of the surface at the +Y′-axis side of the lid plate 110. On the surface at the +Y′-axis side of the lid plate 110, the pair of the lid films 113 is formed at the +X-axis side and the −X-axis side of the lid plate 110. Each lid film 113 is formed to have a length RX in the X-axis direction and a length RZ in the Z′-axis direction.

The mounting terminal 124 formed on the base plate 120 and the lid film 113 formed on the lid plate 110 are formed with the same lengths in the X-axis direction and the Z′-axis direction. In other words, the length BX is the same as the length RX and the length BZ is the same as the length RZ. Therefore, the shape and area of the mounting terminal 124 can be considered to be the same as those of the lid film 113.

### Fabrication Method of the Piezoelectric Device 100

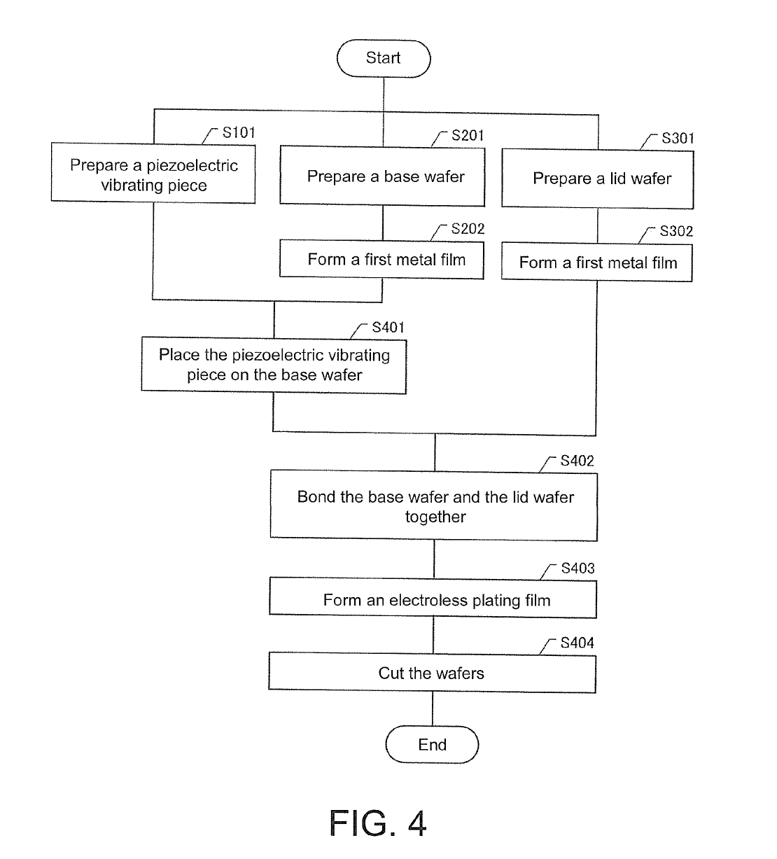

FIG. 4 is a flowchart illustrating a method for fabricating the piezoelectric device 100. A description will be given of the method for fabricating the piezoelectric device 100 following the flowchart of FIG. 4.

in step S101, a plurality of piezoelectric vibrating pieces 130 is prepared. In step S101, first, an outline of a plurality of piezoelectric vibrating pieces 130 is formed on a piezoelectric wafer, which is made of a piezoelectric material, by etching or similar method. Further, the excitation electrode 131 and the extraction electrode 132 are formed on each piezoelectric vibrating piece 130 by a method such as sputtering or vacuum evaporation. The plurality of piezoelectric vibrating pieces 130 is prepared by dicing into individual piezoelectric vibrating piece 130 so as to be folded and removed from the piezoelectric wafer.

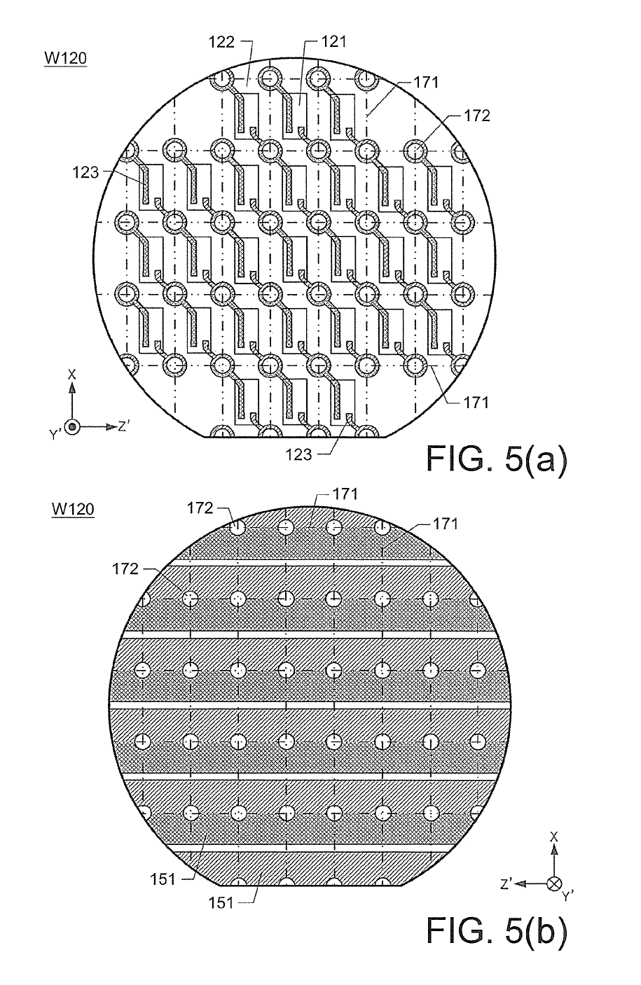

In step S201, the base wafer W120 is prepared. A plurality of base plates 120 is formed on the base wafer W120. The base wafer W120 employs a material such as a crystal or a glass as the base material. In the base wafer W120, the depressed portion 121 and a through hole 172 (see FIG. 5(a)), which becomes the castellation 126 by dicing the wafer, are formed by etching.

In step S202, the first metal film 151 is formed on the base wafer W120.

Step S202 is a process for forming a metal film for a base. The first metal film 151, which is formed on the base wafer W120, is formed of the first layer 151a, the second layer 151b, and the third layer 151c as illustrated in FIG. 2(b). A chrome (Cr) constitutes the first layer 151a, a nickel tungsten (Ni—W) constitutes the second layer 151b, and a gold (Au) constitutes the third layer 151c. These layers are formed by sputtering or vacuum evaporation. In step S202, formation of the first metal film 151 forms the connecting electrode 123, a part of the side surface electrode 125, and a part of mounting terminal 124 on each base plate 120.

FIG. 5(a) is a plan view of the surface at the +Y′-axis side of the base wafer W120. The first metal film 151 is formed on the base wafer W120 illustrated in FIG. 5(a). The base wafer W120 includes a plurality of base plates 120 that are each aligned in the X-axis direction and the Z′-axis direction. In FIG. 5(a), a scribe line 171 is illustrated at a boundary between the base plates 120 adjacent one another. The scribe line 171 is a line that indicates a position at which the wafer is diced in step S404, which will be described below. The through hole 172 passing through the base wafer W120 through the Y′-axis direction are formed at a position where the scribe line 171 that extends in the X-axis direction intersect with the scribe line 171 that extends in the Z′-axis direction. After the wafer is diced in step S404, which will be described below, the through hole 172 becomes the castellations 126. The depressed portion 121 is formed on the surface at the +Y′-axis side of each base plate 120. The connecting electrode 123 is formed on the surface at the +Y′-axis side of each base plate 120.

FIG. 5(b) is a plan view of the surface at the −Y′-axis side of the base wafer W120. The first metal film 151, which becomes a part of the mounting terminal 124, is formed on the surface at the −Y′-axis side of the base wafer W120. The first metal film 151 is electrically connected to the connecting electrode 123 via the side surface electrode 125 formed on the through hole 172. The first metal film 151 is formed as can be extended in the Z′-axis direction of the base wafer W120.

Returning to FIG. 4, in step S301, the lid wafer W110 is prepared. A plurality of lid plates 110 is formed on the lid wafer W110. The depressed portion 111 is formed on the surface at the −Y′-axis side of each lid plate 110.

In step S302, the first metal film 151 is formed on the lid wafer W110. Step S302 is a process for forming a metal film for a lid. The first metal film 151, which is formed on the lid wafer W110, is formed of the first layer 151a, the second layer 151b, and the third layer 151c as illustrated in FIG. 2(c). A chrome (Cr) constitutes the first layer 151a, a nickel tungsten (Ni—W) constitutes the second layer 151b, and a gold (Au) constitutes the third layer 151c. These layers are formed by sputtering or vacuum evaporation. In step S302, formation of the first metal film 151 forms a part of the lid film 113 on each base plate 120.

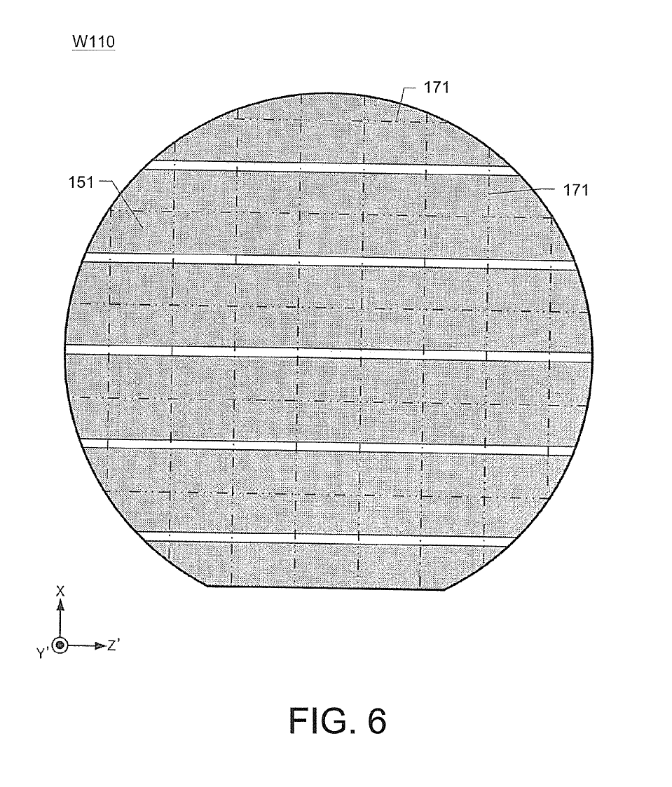

FIG. 6 is a plan view of the surface at the +Y′-axis side of the lid wafer W110. The plurality of lid plates 110 are formed on the lid wafer W110, and the depressed portion 111 and the bonding surface 112 are formed on the surface at the −Y′-axis side of each lid plate 110 (see FIG. 1). As shown in FIG. 6, the distance between the respective adjacent lid plates 110 is indicated by a double-dashed chain line that serves as the scribe line 117. Besides, the first metal film 151 that becomes the part of the lid film 113 is formed on the surface at the +Y′-axis side of each lid plate 110. The first metal film 151 formed on the lid wafer W110 is formed so as to be extended in the Z′-axis direction as with the first metal film 151 formed on the base wafer W120.

In step S401, the piezoelectric vibrating piece 130 is placed on the base wafer W120. Step S401 is a placement process. The piezoelectric vibrating piece 130 is placed on each depressed portion 121 on the base wafer W120 with the conductive adhesive 141.

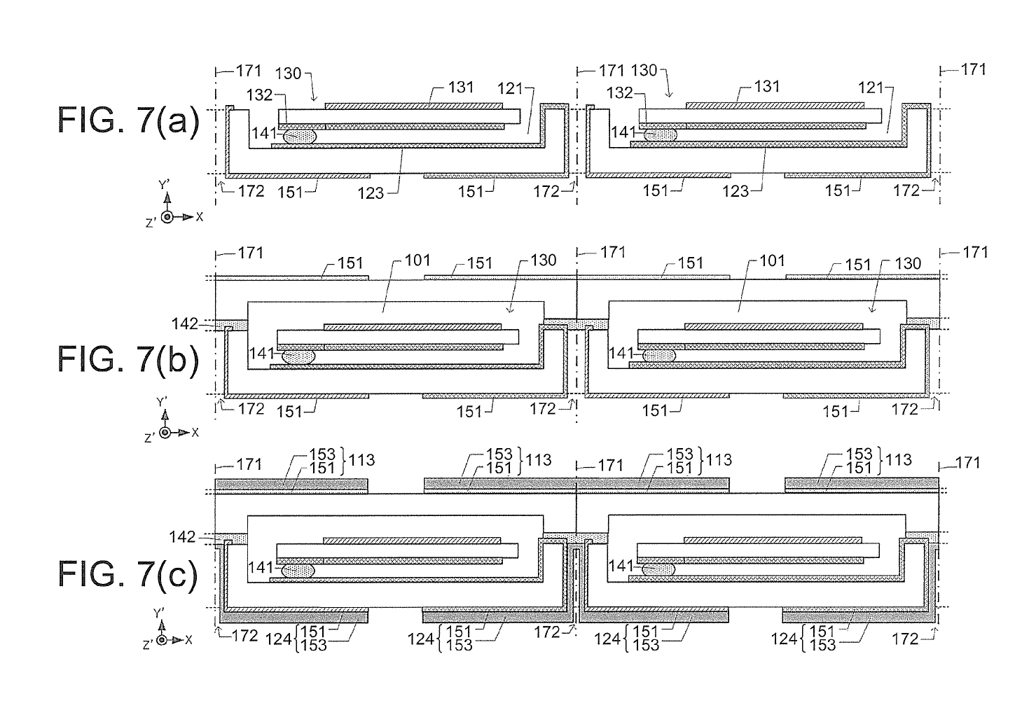

FIG. 7(a) is a partial cross-sectional view of the base wafer W120 where the piezoelectric vibrating piece 130 is placed. FIG. 7(a) illustrates a cross-sectional view including a cross section corresponding to the cross section taken along the line IIA-IIA of FIG. 1. The extraction electrode 132 and the connecting electrode 123 are electrically connected together via the conductive adhesive 141. Thus, the piezoelectric vibrating piece 130 is placed on the depressed portion 121 of the base wafer W120. This electrically connects the excitation electrode 131 and the first metal film 151, which is formed on the surface at the −Y′-axis side of the base wafer W120.

In step S402, the base wafer W120 and the lid wafer W110 are bonded together. Step S402 is a bonding process. The base wafer W120 and the lid wafer W110 are bonded together as follows. The sealing material 142 (see FIG. 2(a)) is applied to the bonding surface 122 of the base wafer W120 or the bonding surface 112 of the lid wafer W110. Then, the bonding surface 122 of the base wafer W120 and the bonding surface 112 of the lid wafer W110 are bonded together such that they face each other while sandwiching the sealing material 142.

FIG. 7(b) is a partial cross-sectional view of the lid wafer W110, the piezoelectric vibrating piece 130, and the base wafer W120. FIG. 7(b) illustrates a cross-sectional view including a cross section similar to FIG. 7(a). The lid wafer W110 and the base wafer W120 are bonded together via the sealing material 142. Thus, the sealed cavity 101 is formed. The piezoelectric vibrating piece 130 is placed in the cavity 101.

In step S403, the electroless plating film 153 is formed. Step S403 is a process of electroless plating. In step S403, the electroless plating films 153 are formed by performing electroless plating on the surfaces of the first metal films 151, which are formed on the surface of the lid wafer W110 at the +Y′-axis side and on the surface of the base wafer W120 at the −Y′-axis side. The electroless plating film 153 is formed on the surface of the lid wafer W110 at the +Y′-axis side on the surface at the −Y′-axis side of the base wafer W120, and a side surface of the through hole 172.

FIG. 7(c) is a partial cross-sectional view of the lid wafer W110 where the electroless plating film 153 is formed, the piezoelectric vibrating piece 130, and the base wafer W120 where the electroless plating film 153 is formed. FIG. 7(c) illustrates a cross-sectional view of the cross section similar to FIG. 7(b). First, the electroless plating film 153 is formed as illustrated in FIG. 2(b). A thick film of a nickel (Ni) is formed on a surface of the first metal film 151 by electroless plating so as to form the first layer 153a. Further, sputtering or vacuum evaporation is performed with a gold (Au) on the surface of the first layer 153a, thus the second layer 153b is formed. The second layer 153b may be formed of the gold (Au) layer by the electroless plating.

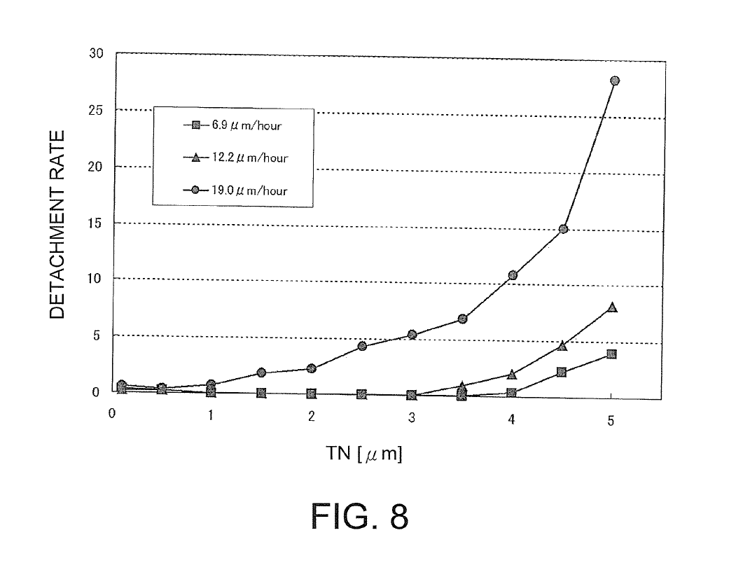

FIG. 8 is a graph illustrating a relationship between the thickness TN of a nickel (Ni) layer of the electroless plating film 153 and a detachment rate of the electroless plating film 153. FIG. 8 illustrates results in the case where the nickel (Ni) layer of the electroless plating film 153 is formed at three speeds: 6.9 μm/hour, 12.2 μm/hour, and 19.0 μm/hour. In the graph, the black square indicates a formation speed of 6.9 μm/hour, the black triangle indicates a formation speed of 12.2 μm/hour, and the black circle indicates a formation speed of 19.0 μm/hour. The formation speed can be adjusted, for example, by a temperature condition. The following is assumed. When the formation speed is 6.9 μm/hour, the temperature is 45° C. to 55° C. When the formation speed is 12.2 μm/hour, the temperature is 60° C. to 70° C. When the formation speed is 19.0 μm/hour, the temperature is 70° C. to 80° C. The detachment rate is obtained by performing the following methods. A scratch test confirms whether the metal film detaches or not by scratching a surface of the metal film with a metal needle or a diamond stylus. A tape peeling test confirms whether the metal film detaches or not by peeling a tape pasted on the metal film. The detachment rate in FIG. 8 indicates a rate of the number of individuals from which the metal film is detached relative to the number of individuals that are target for the tests.

In the case where the formation speeds are 6.9 μm/hour and 12.2 μm/hour, the detachment rate exists but is small when the thickness TN of the nickel layer is 0.1 μm to 1 μm. This is possibly because when the thickness TN of the nickel layer is thin, the nickel layer is not completely secured to the surface of the metal film. In the case where the formation speed is 6.9 μm/hour, the detachment rate is 0% at the thickness TN of between 1 μm to 3.5 μm and increases when the thickness TN becomes equal to or more than 3.5 μm. In the case where the formation speed is 12.2 μm/hour, the detachment rate is 0% at the thickness TN of between 1 μm to 3 μm and increases when the thickness TN becomes equal to or more than 3 μm. In the case where the formation speed is 19.0 μm/hour, the detachment rate exists but is small when the thickness TN of the nickel layer is 0.1 μm to 1 μm. In the case where the thickness TN is 1 μm, the detachment rate becomes the lowest value. In the case where the thickness TN is equal to or more than 1 μm, the detachment rate increases as the thickness TN becomes thick.

It can be seen from the graph of FIG. 8, when the formation speed of the nickel layer is from 6.9 μm/hour to 12.2 μm/hour and the thickness TN of the nickel layer is 1.0 μm to 3.0 μm, the detachment rate becomes 0%. This is a preferred condition. Further, it is considered when the formation speed of the nickel layer is from 5 μm/hour to 15 μm/hour, at least the detachment rate becomes 0% or a value close to 0%. This is a preferred condition.

Returning to FIG. 4, in step S404, the lid wafer W110 and the base wafer W120 are cut off. In the scribe line 171, the lid wafer W110 and the base wafer W120 are cut off by dicing, or similar method.

In the wafer formed with an electroless plating film, stress occurs according to the length of the electroless plating film. For example, in the case of the electroless plating film 153 is formed on the surface of the first metal film 151 of the base wafer W120 illustrated in FIG. 5(b), since the electroless plating film 153 is formed long in the Z′-axis direction, strong stress is applied in the Z′-axis direction. Thus, the surface at the −Y′-axis side of the base wafer W120 is warped into a depressed shape. In addition, this stress varies by cutting the wafer in step S404, which causes strain in the piezoelectric device. The mounting terminal formed on the piezoelectric device may be detached by this strain. In the piezoelectric device 100, since the lid film 113 is formed as the same shape and the same area as the mounting terminal 124 on the lid plate 110, stress on the surface at the +Y′-axis side and the surface at the −Y′-axis side in the piezoelectric device 100 are balanced. Thus, the piezoelectric device 100 has no strain. As a result, after the cutting of the wafer is completed, the detachment of the mounting terminal caused by stress in the electroless plating film can be avoided in the piezoelectric device 100.

With the piezoelectric device 100, the detachment rate of the electroless plating film 153 can be reduced by the following. The formation speed of the nickel layer of the electroless plating film 153 is set to 5 μm/hour to 15 μm/hour, and the thickness TN of the nickel layer is set to 1 μm to 3 μm.

At the four corners of the side surfaces of the lid plate 110 of the piezoelectric device 100, a castellation similar to the castellation 126 of the base plate 120 may be formed. In this case, the castellation formed on the lid plate 110 and the castellation formed on the base plate 120 are connected to each other in the Y′-axis direction, and the mounting terminal 124 and the lid film 113 are electrically connected to each other by the electroless plating film 153 formed in step S403 of FIG. 4. In such piezoelectric device, the top and bottom of the piezoelectric device can be turned upside down so as to be capable of utilizing the lid film 113 as the mounting terminal.

### Second Embodiment

A piezoelectric vibrating piece that includes a framing portion surrounding a peripheral area of a vibrating portion may be employed as a piezoelectric vibrating piece. A description will be given of a piezoelectric device 200 where a piezoelectric vibrating piece with a framing portion is employed. The embodiment will now be described wherein like reference numerals designate corresponding or identical elements throughout the embodiments.

### Constitution of the Piezoelectric Device 200

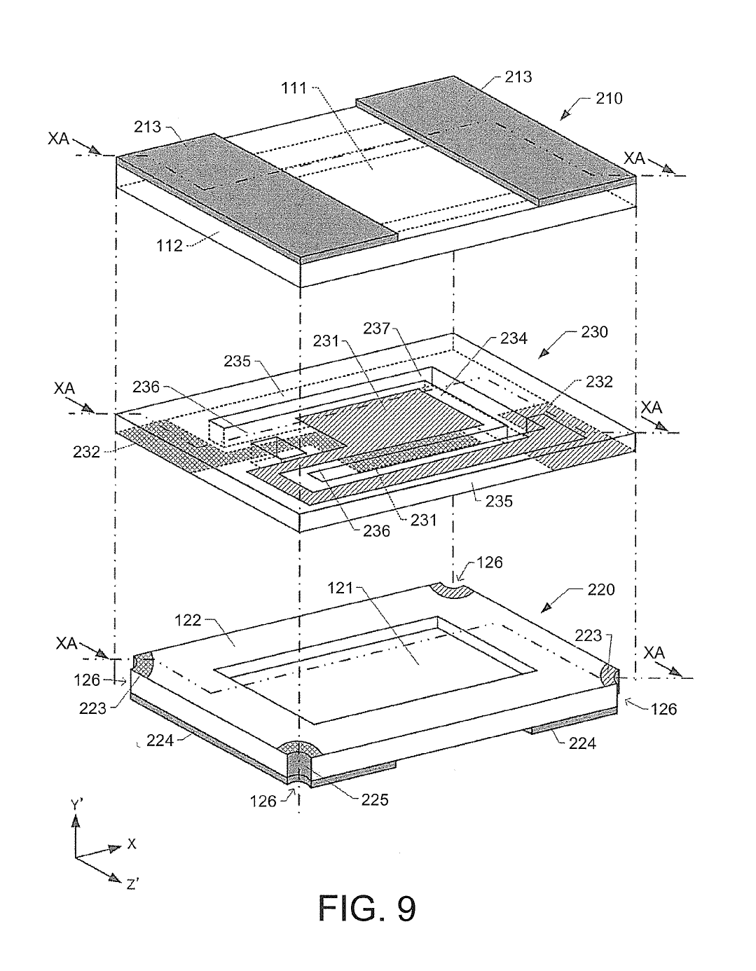

FIG. 9 is an exploded perspective view of the piezoelectric device 200. The piezoelectric device 200 includes a lid plate 210, a base plate 220, and a piezoelectric vibrating piece 230. With the piezoelectric device 200, similarly to the first Embodiment, an AT-cut quartz-crystal vibrating piece is employed for the piezoelectric vibrating piece 230.

The piezoelectric vibrating piece 230 includes a vibrating portion 234, a framing portion 235, and a connecting portion 236. The vibrating portion 234 vibrates at a predetermined frequency and has a rectangular shape. The framing portion 235 is formed to surround a peripheral area of the vibrating portion 234. The connecting portion 236 connects the vibrating portion 234 and the framing portion 235. Between the vibrating portion 234 and the framing portion 235, a through groove 237 that passes through the piezoelectric vibrating piece 230 in the Y′-axis direction is formed. The vibrating portion 234 and the framing portion 235 do not directly contact one another. The vibrating portion 234 and the framing portion 235 are connected together via the connecting portion 236 connected at the −X-axis side and the +Z′-axis side, and at the −X-axis side and the −Z′-axis side of the vibrating portion 234. Further, excitation electrodes 231 are formed on surfaces of the +Y′-axis side and the −Y′-axis side of the vibrating portion 234. An extraction electrode 232 is extracted from each excitation electrode 231 to the framing portion 235. The extraction electrode 232 is extracted from the excitation electrode 231, which is formed on the surface at the +Y′-axis side of the vibrating portion 234. The extraction electrode 232 is extracted to the −X-axis side of the framing portion 235 via the connecting portion 236 at the +Z′-axis side and further extracted to the corner at the +X-axis side and the +Z′-axis side on the surface at the −Y′-axis side of the framing portion 235. The extraction electrode 232 is extracted from the excitation electrode 231, which is formed on the surface at the −Y′-axis side of the vibrating portion 234. The extraction electrode 232 is extracted to the −X-axis side of the framing portion 235 via the connecting portion 236 at the −Z′-axis side, and is further extracted up to the corner at the −X-axis side and the −Z′-axis side on the surface at the −Y′-axis side of the framing portion 235.

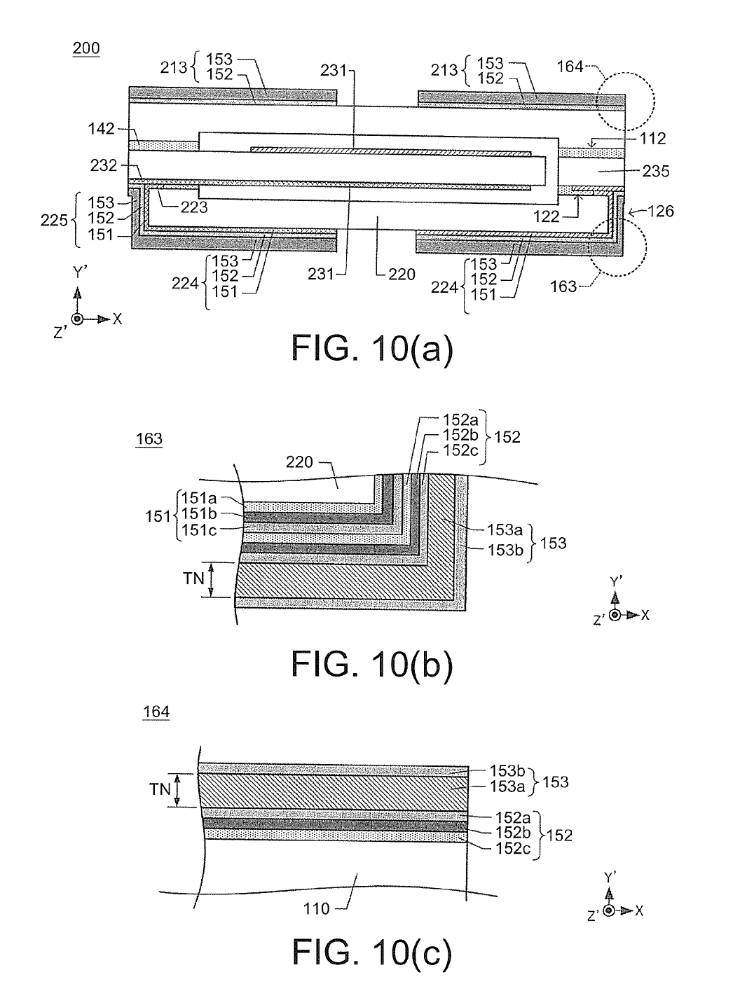

A bonding surface 122 is formed at the peripheral area of the surface at the +Y′-axis side of the base plate 220. The bonding surface 122 is to be bonded to the lid plate 210 via a sealing material 142 (see FIG. 10(a)). The base plate 220 includes a depressed portion 121 at the center of the surface at the +Y′-axis side. The depressed portion 121 is depressed from the bonding surface 122 in the −Y′-axis direction. A mounting terminal 224 is formed on the surface at the −Y′-axis side of the base plate 220. A castellation 126 is formed at a corner on the side surfaces of the base plate 220. A connecting electrode 223 is formed at the peripheral area of the castellation 126 of the bonding surface 122. The connecting electrode 223 is electrically connected to the mounting terminal 224 via a side surface electrode 225 formed on the castellation 126.

On the lid plate 210, a depressed portion 111 is formed on the surface at the −Y′-axis side, and a bonding surface 112 is formed at the peripheral area of the depressed portion 111. Moreover, a lid film 213 is formed at the +X-axis side and the −X-axis side on the surface at the +Y′-axis side of the lid plate 210. The lid film 213 is formed with the same shape and the same area as the mounting terminal 224.

FIG. 10(a) is a cross-sectional view taken along the line XA-XA of FIG. 9. The piezoelectric device 200 is formed by bonding the bonding surface 112 of the lid plate 210 and the surface at the +Y′-axis side of the framing portion 235 together via the sealing material 142. The bonding surface 122 of the base plate 220 and the surface at the −Y′-axis side of the framing portion 235 are bonded together via the sealing material 142. The extraction electrode 232 and the connecting electrode 223 are electrically bonded together at the bonding of the piezoelectric vibrating piece 230 and the base plate 220. This electrically connects the excitation electrode 231 to the mounting terminal 224. The mounting terminal 224 are formed of the first metal film 151, a second metal film 152, and the electroless plating film 153. Furthermore, the lid film 213 is formed of the second metal film 152 and the electroless plating film 153.

FIG. 10(b) is an enlarged view of the portion enclosed by a dotted line 163 of FIG. 10(a). FIG. 10(b) illustrates an enlarged cross-sectional view of the mounting terminal 224. The first metal film 151 is formed of three layers: a first layer 151a, a second layer 151b, and a third layer 151c. As illustrated in FIG. 2(b), the first layer 151a is made of a chrome (Cr), the second layer 151b is made of a nickel tungsten (Ni—W), a platinum (Pt), or similar material, and the third layer 151c is made of a gold (Au).

The second metal film 152 includes a first layer 152a, a second layer 152b, and a third layer 152c. The first layer 152a is formed on the surface of the first metal film 151. The second layer 152b is formed on the surface of the first layer 152a. The third layer 152c is formed on the surface of the second layer 152b. The first layer 152a, the second layer 152b, and the third layer 152c are formed of the same constitution as the first layer 151a, the second layer 151b, and the third layer 151c of the first metal film 151, respectively. In short, the second metal film 152 is formed of the same constitution as the first metal film 151.

The electroless plating film 153 is formed of the first layer 153a and the second layer 153b. The first layer 153a is formed on a surface of the second metal film 152. The second layer 153b is formed on a surface of the first layer 153a. The first layer 153a is a nickel (Ni) layer and has the thickness TN of 1 μm to 3 μm. To ensure connection of the mounting terminals 224 and a solder or similar material, the second layer 153b made of a gold (Au) is formed on a surface of the first layer 153a.

FIG. 10(c) is an enlarged view of a dotted line 164 of FIG. 10(a). FIG. 10(c) illustrates an enlarged cross-sectional view of the lid film 213. The lid film 213 is formed of the second metal film 152 formed on the surface at the +Y′-axis side of the base material of the lid plate 210 and the electroless plating film 153 is formed on the surface of the second metal film 152. The second metal film 152 and the electroless plating film 153 forming the lid film 213 are formed as the same configuration as the first metal film 151 and the electroless plating film 153 of the lid film 113 as illustrated in FIG. 2(c).

### Fabrication Method of the Piezoelectric Device 200

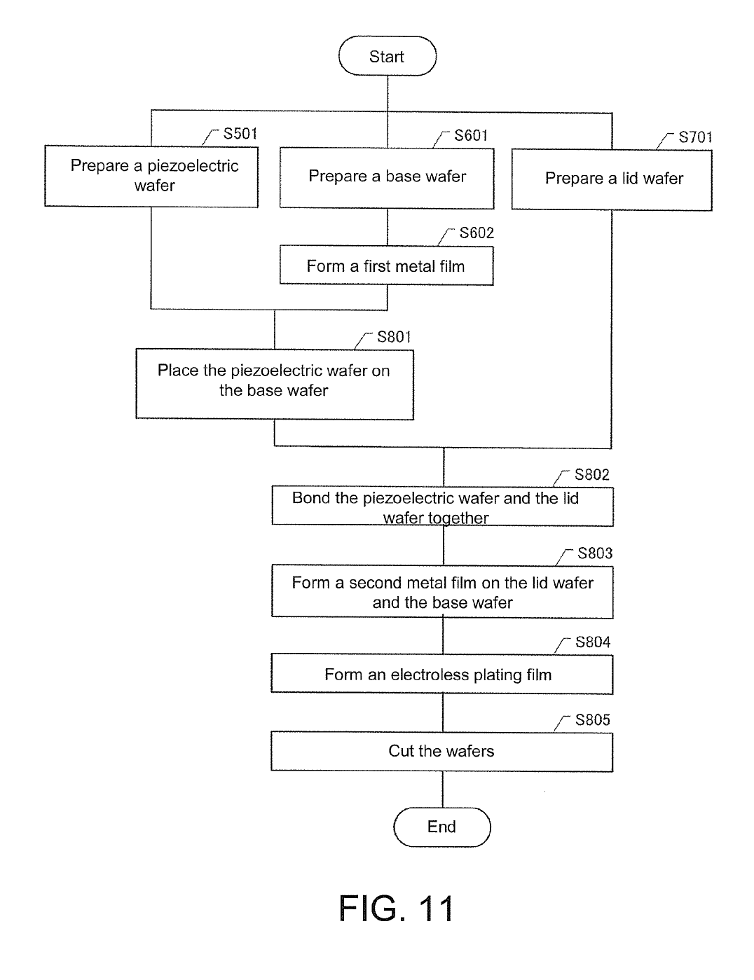

FIG. 11 is a flowchart illustrating a method for fabricating the piezoelectric device 200. A description will be given of the method for fabricating the piezoelectric device 200 following the flowchart of FIG. 11.

In step S501, a piezoelectric wafer W230 is prepared. A plurality of piezoelectric vibrating pieces 230 is formed on the piezoelectric wafer W230. Step S501 is a process for preparing a piezoelectric wafer.

In step S601, a base wafer W220 is prepared. A plurality of base plates 220 is formed on the base wafer W220. Step S601 is a process for preparing the base wafer W220.

In step S602, a first metal film 151 is formed on the base wafer W220. As illustrated in FIG. 10(a), the first metal film 151 forms a part of a connecting electrode 223, a-side surface electrode 225, and a mounting terminal 224. The step S602 is a step of forming a metal film for a base.

In step S701, a lid wafer W210 is prepared. A plurality of lid plates 210 is formed on the lid wafer W210. Step S701 is a process for forming the lid wafer W210.

In step S801, the piezoelectric wafer W230 is placed on the base wafer W220. Step S801 is a placement process where the base wafer W220 and the piezoelectric wafer W230 are bonded together such that each piezoelectric vibrating piece 230 of the piezoelectric wafer W230 is placed corresponding to the surface at the +Y′-axis side of each base plate 220 of the base wafer W220. In this placement process, the bonding surface 122 of the base wafer W220 is bonded on the surface at the −Y′-axis side of the framing portion 235, which is formed on the piezoelectric wafer W230, via the sealing material 142.

In step S802, the piezoelectric wafer W230 and the lid wafer W210 are bonded together. Step S802 is a bonding process where the lid wafer W210 is bonded to the surface at the +Y′-axis side of the piezoelectric wafer W230 via the sealing material 142, so as to seal the vibrating portion 234 of the piezoelectric vibrating piece 230.

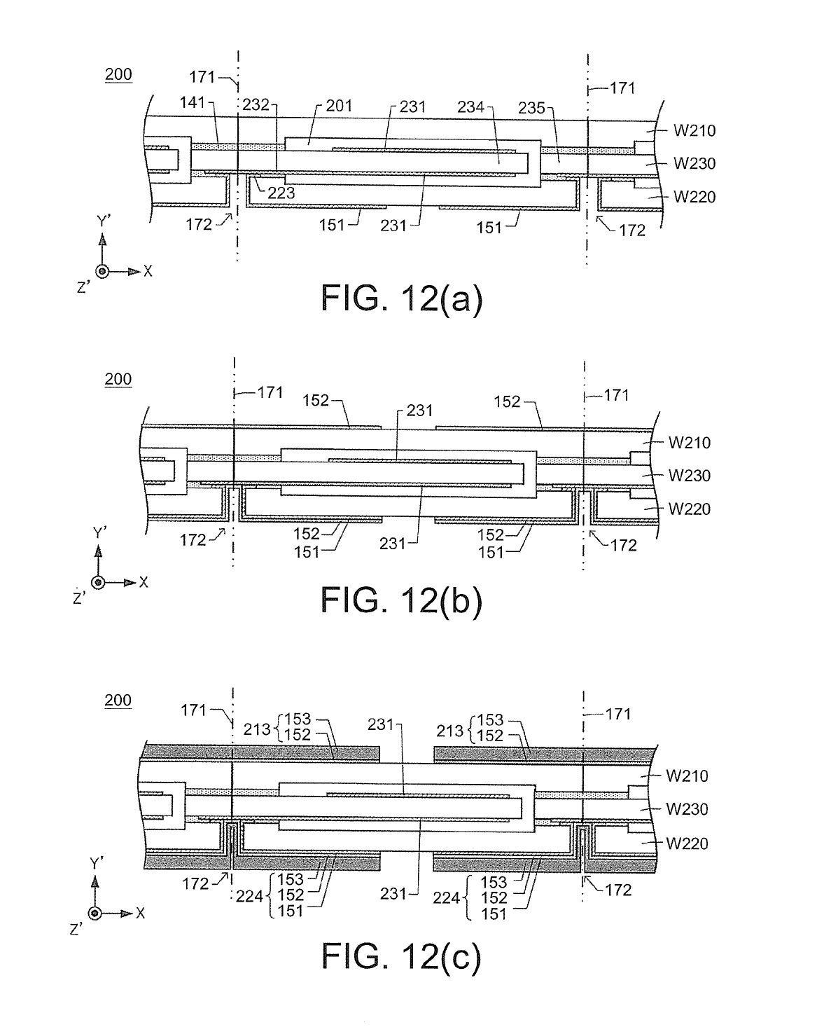

FIG. 12(a) is a partial cross-sectional view of the piezoelectric wafer W230, the lid wafer W210, and the base wafer W220. FIG. 12(a) is a cross-sectional view including a cross section taken along the line XA-XA of FIG. 9. The base wafer W220 is bonded to the surface at the −Y′-axis side of the framing portion 235 of the piezoelectric wafer W230 via the sealing material 142. The connecting electrode 223 electrically connects to the extraction electrode 232. The lid wafer W210 is bonded to the surface at the +Y′-axis side of the framing portion 235 of the piezoelectric wafer W230 via the sealing material 142. This forms a cavity 201 in the wafer, and the vibrating portion 234 is sealed into this cavity 201.

In step S803, the second metal film 152 is formed on the lid wafer W210 and the base wafer W220.

FIG. 12(b) is a partial cross-sectional view of the piezoelectric wafer W230, the lid wafer W210 and the base wafer W220 formed with the second metal film 152. Similarly to the mounting terminal 124 and the lid film 113 illustrated in FIG. 3(a) and FIG. 3(b), both the second metal film 152 formed on the lid wafer W210 and the second metal film 152 formed on the base wafer W220 are formed so that the X-axis direction lengths are equal to each other. In addition, the second metal film 152 is formed so as to be extended in the Z′-axis direction on the surface at the −Y′-axis side of the base wafer W220 and the surface at the +Y′-axis side of the lid wafer W210, similarly to the first metal film 151 formed on the base wafer W120 illustrated in FIG. 5(b) and the first metal film 151 formed on the lid wafer W110 illustrated in FIG. 6.

In step S804, the electroless plating film 153 is formed on the base wafer W220 and the lid wafer W210. The electroless plating film 153 is formed on the surface of the second metal film 152 formed on the base wafer W220 and the lid wafer W210.

FIG. 12(c) is a partial cross-sectional view of the piezoelectric wafer W230, and the lid wafer W210 and the base wafer W220 where the electroless plating films 153 are formed. The electroless plating films 153, which are formed on the lid wafer W210 and the base wafer W220, are formed on the surfaces of the second metal film 152. A nickel layer, which forms the electroless plating film 153, is formed to have the thickness TN of 1 μm to 3 μm at a deposition rate of 5 to 15 μm/hour.

In step S805, the base wafer W220, the lid wafer W210, and the piezoelectric wafer W230 are diced at the scribe line 171. Thus, individual piezoelectric devices 200 are formed.

In the piezoelectric device 200, similarly to the piezoelectric device 100, since strain applied to the piezoelectric device 200 can be suppressed by forming the lid film 213 with the same shape and the same area as the mounting terminal 224 on the lid wafer W210. This prevents the mounting terminal 224 from detachment. In a piezoelectric device, an electroless plating film may not be formed due to contamination of the surface of the metal film, which becomes a foundation layer, or similar cause. With the piezoelectric device 200, formation of the second metal film 152, which becomes a foundation layer, immediately before performing electroless plating suppresses influence by minimizing contamination of the foundation layer or similar cause.

In the piezoelectric device 200, the mounting terminal 224 of the base plate 220 and the side surface electrode 225 are formed of the first metal m 151, the second metal film 152, and the electroless plating film 153. However, similarly to the piezoelectric device 100, it may be formed of the first metal film 151 and the electroless plating film 153, not including the second metal film 152. At this moment, in step S803 of the flowchart of FIG. 11, the second metal film 152 is formed only on the lid wafer W210, and the second metal film 152 is not formed on the base wafer W220.

Representative embodiments are described in detail above; however, as will be evident to those skilled in the relevant art, this disclosure may be changed or modified in various ways within its technical scope.

For example, an oscillator may be embedded to the piezoelectric device, so as to form a piezoelectric oscillator. Also, although the first metal film or the second metal film is formed so as to form the electroless plating film on the lid plate, these metal films may be formed of an area larger than the electroless plating film. For example, in some cases, a sputtering film is formed on the lid plate that a serial number or similar are printed on the surface of the sputtering film by laser processing; however, the electroless plating film may be formed on this surface of the sputtering film.

Additionally, the above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalate, lithium niobate, and piezoelectric ceramic.

In the first aspect of the disclosure, the piezoelectric device according to a second aspect is configured as follows. The piezoelectric vibrating piece includes the vibrating portion, a framing portion surrounding the vibrating portion, and a connecting portion connecting the vibrating portion and the framing portion. The base plate and the lid plate are bonded together via the framing portion.

In the first aspect or the second aspect of the disclosure, the piezoelectric device according to a third aspect is configured as follows. The metal film includes a chromium layer, a nickel tungsten layer, and a gold layer. The nickel tungsten layer is formed on a surface of the chromium layer. The gold layer is formed on a surface of the nickel tungsten layer.

In the first aspect or the second aspect of the disclosure, the piezoelectric device according to a fourth aspect is configured as follows. The metal film includes a chromium layer, a platinum layer, and a gold layer. The platinum layer is formed on a surface of the chromium layer. The gold layer is formed on a surface of the platinum layer.

In the third aspect or the fourth aspects of the disclosure, the piezoelectric device according to a fifth aspect is configured as follows. The pair of mounting terminals includes the metal film with two layers. The electroless plating film is also formed on a surface of the metal film.

In the first aspect or the fifth aspect of the disclosure, the piezoelectric device according to a sixth aspect is configured as follows. The electroless plating film includes a nickel layer with a film thickness ranging from 1 μm to 3 μm.

In the sixth aspect of the disclosure, the piezoelectric device according to a seventh aspect is configured as follows. The electroless plating film includes a gold layer on a surface of the nickel layer.

According to the eighth aspect, a method for fabricating a surface mount piezoelectric device includes: preparing a plurality of piezoelectric vibrating pieces including a vibrating portion that vibrates at a predetermined vibration frequency; preparing a base wafer including a plurality of base plates; forming a metal film on one principal surface of the base wafer by sputtering or vacuum evaporation; preparing a lid wafer including a plurality of lid plates; placing the plurality of piezoelectric vibrating pieces on the other principal surface of the base wafer; bonding the other principal surface of the lid wafer to the other principal surface of the base wafer so as to seal the vibrating portion; and forming a metal film on one principal surface of the lid wafer after the preparing of the lid wafer and before the placing or after the bonding; and applying electroless plating on the metal film of the base wafer and the metal film of the lid wafer. The electroless plating film formed on the lid wafer has a same shape and a same area as a shape and an area of the electroless plating film of the base wafer.

According to the ninth aspect, a method for fabricating a surface mount piezoelectric device includes: preparing a piezoelectric wafer that includes a plurality of piezoelectric vibrating pieces including a vibrating portion that vibrates at a predetermined vibration frequency, a framing portion surrounding the vibrating portion, and a connecting portion connecting the vibrating portion and the framing portion; preparing a base wafer including a plurality of base plates; forming a metal film on one principal surface of the base wafer by sputtering or vacuum evaporation; preparing a lid wafer including a plurality of lid plates; bonding the base wafer and the piezoelectric wafer so as to place the respective piezoelectric vibrating pieces on the other principal surface of the base plate; bonding the other principal surface of the lid wafer to the other principal surface of the piezoelectric wafer so as to seal the vibrating portion; and forming a metal film on one principal surface of the lid wafer after the preparing of the lid wafer and before the placing or after the bonding; and applying electroless plating on the metal film formed on the one principal surface of the base wafer and the metal film of the lid wafer. The electroless plating film formed on the lid wafer has a same shape and a same area as a shape and an area of the electroless plating film of the base wafer.

In the eighth aspect and the ninth aspect of the disclosure, the method for fabricating the surface mount piezoelectric device according to a tenth aspect is configured as follows. The metal film includes a chromium layer, a nickel tungsten layer, and a gold layer. The nickel tungsten layer is formed on a surface of the chromium layer. The gold layer is formed on a surface of the nickel tungsten layer.

In the eighth aspect and the ninth aspect of the disclosure, the method for fabricating the surface mount piezoelectric device according to an eleventh aspect is configured as follows. The metal film includes a chromium layer, a platinum layer, and a gold layer. The platinum layer is formed on a surface of the chromium layer. The gold layer is formed on a surface of the platinum layer.

In the eighth aspect and the eleventh aspect of the disclosure, the method for fabricating the surface mount piezoelectric device according to a twelfth aspect further includes forming the metal film again on the other principal surface of the base wafer after the bonding and before the electroless plating.

In the eighth aspect and the twelfth aspect of the disclosure, the method for fabricating the surface mount piezoelectric device according to a thirteenth aspect is configured as follows. The electroless plating film includes a nickel layer. The nickel layer is formed at a deposition rate of 5 to 15 μm/hour.

In the thirteenth aspect of the disclosure, the method for fabricating the surface mount piezoelectric device according to a fourteenth aspect is configured as follows. The nickel layer of the electroless plating film has a film thickness in a range of 1 μm to 3 μm.

With the piezoelectric device and the method for fabricating the piezoelectric device according to the embodiments, detachment of an electrode formed by electroless plating can be avoided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A surface mount piezoelectric device, comprising:
a piezoelectric vibrating piece that includes a vibrating portion that vibrates at a predetermined vibration frequency;
a base plate having one principal surface and another principal surface, the one principal surface including a pair of mounting terminals, the piezoelectric vibrating piece being placed on the other principal surface, the pair of mounting terminals including a metal film formed by sputtering or vacuum evaporation and an electroless plating film formed on a surface of the metal film, the piezoelectric device being to be mounted with the pair of mounting terminals; and
a lid plate having one principal surface and another principal surface, the one principal surface including a metal film and an electroless plating film formed on a surface of the metal film by electroless plating, the other principal surface sealing the vibrating portion, wherein
the electroless plating film formed on the one principal surface of the base plate and the electroless plating film formed on the one principal surface of the lid plate have mutually a same shape and a same area.

2. The piezoelectric device according to claim 1, wherein
the piezoelectric vibrating piece includes: the vibrating portion, a framing portion for surrounding the vibrating portion, and a connecting portion for connecting the vibrating portion and the framing portion, and
the base plate and the lid plate are bonded together via the framing portion.

3. The piezoelectric device according to claim 1, wherein
the metal film includes: a chromium layer, a nickel tungsten layer, and a gold layer,
the nickel tungsten layer is formed on a surface of the chromium layer, and
the gold layer is formed on a surface of the nickel tungsten layer.

4. The piezoelectric device according to claim 1, wherein
the metal film includes: a chromium layer, a platinum layer, and a gold layer,
the platinum layer is formed on a surface of the chromium layer, and
the gold layer is formed on a surface of the platinum layer.

5. The piezoelectric device according to claim 3, wherein
the pair of mounting terminals includes: the metal film with two layers, and
the electroless plating film is also formed on a surface of the metal film.

6. The piezoelectric device according to claim 1, wherein
the electroless plating film includes: a nickel layer with a film thickness ranging from 1 μm to 3 μm.

7. The piezoelectric device according to claim 6, wherein
the electroless plating film includes: a gold layer on a surface of the nickel layer.

8. A method for fabricating a surface mount piezoelectric device, comprising:
preparing a plurality of piezoelectric vibrating pieces including a vibrating portion that vibrates at a predetermined vibration frequency;
preparing a base wafer including a plurality of base plates;
forming a metal film on one principal surface of the base wafer by sputtering or vacuum evaporation;
preparing a lid wafer including a plurality of lid plates;
placing the plurality of piezoelectric vibrating pieces on the other principal surface of the base wafer;
bonding the other principal surface of the lid wafer to the other principal surface of the base wafer so as to seal the vibrating portion; and
forming a metal film on one principal surface of the lid wafer after the preparing of the lid wafer and before the placing or after the bonding; and
applying electroless plating on the metal film of the base wafer and the metal film of the lid wafer, wherein
the electroless plating film formed on the lid wafer has a same shape and a same area as a shape and an area of the electroless plating film of the base wafer.

9. A method for fabricating a surface mount piezoelectric device, comprising:
preparing a piezoelectric wafer that includes a plurality of piezoelectric vibrating pieces including a vibrating portion that vibrates at a predetermined vibration frequency, a framing portion for surrounding the vibrating portion, and a connecting portion for connecting the vibrating portion and the framing portion;
preparing a base wafer including a plurality of base plates;
forming a metal film on one principal surface of the base wafer by sputtering or vacuum evaporation;
preparing a lid wafer including a plurality of lid plates;
bonding the base wafer and the piezoelectric wafer so as to place the respective piezoelectric vibrating pieces on the other principal surface of the base plate;
bonding the other principal surface of the lid wafer to the other principal surface of the piezoelectric wafer so as to seal the vibrating portion; and
forming a metal film on one principal surface of the lid wafer after the preparing of the lid wafer and before the placing or after the bonding; and
applying electroless plating on the metal film formed on the one principal surface of the base wafer and the metal film of the lid wafer, wherein
the electroless plating film formed on the lid wafer has a same shape and a same area as a shape and an area of the electroless plating film of the base wafer.

10. The method for fabricating the piezoelectric according to claim 8, wherein
the metal film includes: a chromium layer, a nickel tungsten layer, and a gold layer,
the nickel tungsten layer is formed on a surface of the chromium layer, and
the gold layer is formed on a surface of the nickel tungsten layer.

11. The method for fabricating the piezoelectric device according to claim 8, wherein
the metal film includes: a chromium layer, a platinum layer, and a gold layer,
the platinum layer is formed on a surface of the chromium layer, and
the gold layer is formed on a surface of the platinum layer.

12. The method for fabricating the piezoelectric device according to claim 8, further comprising:
forming the metal film again on the other principal surface of the base wafer after the bonding and before the electroless plating.

13. The method for fabricating the piezoelectric device according to claim 8, wherein
the electroless plating film includes: a nickel layer, and
the nickel layer is formed at a deposition rate of 5 μm/hour to 15 μm/hour.

14. The method for fabricating the piezoelectric device according to claim 13, wherein
the nickel layer of the electroless plating film has a film thickness in a range of 1 μm to 3 μm.
